(19) United States
(12) Patent Application Publication
(10) Pub. No.: US 2025/0006796 A1
(43) Pub. Date: Jan. 2, 2025

(54) SILICON CARBIDE SUBSTRATE AND METHOD OF MANUFACTURING SILICON CARBIDE SUBSTRATE

(71) Applicant: SUMITOMO ELECTRIC INDUSTRIES, LTD., Osaka (JP)

(72) Inventors: Takahiro SHIIHARA, Osaka (JP); Naoki KAJI, Osaka (JP); Shunsaku UETA, Osaka (JP); Hiroki TAKAOKA, Osaka (JP)

(73) Assignee: SUMITOMO ELECTRIC INDUSTRIES, LTD., Osaka (JP)

(21) Appl. No.: 18/703,652

(22) PCT Filed: Sep. 15, 2022
(86) PCT No.: PCT/JP2022/034583

§ 371 Date: Apr. 22, 2024

(30) Foreign Application Priority Data
Nov. 1, 2021 (JP) 2021-178510

(51) Int. Cl. H01L 29/16; C30B 29/36; H01L 21/02

(52) U.S. Cl. CPC H01L 29/1608; C30B 29/36; H01L 21/02378

(57) ABSTRACT

A silicon carbide substrate includes a first main surface and a second main surface opposite to the first main surface. A void is present in the silicon carbide substrate. An area density of the void in the first main surface is 0.7/cm² or less. A width of the void is 10 μm to 80 μm when viewed in a direction perpendicular to the first main surface. In a cross-section perpendicular to the first main surface, the width of the void decreases from the first surface toward the second surface when viewed in a direction parallel to the first main surface. A depth of the void is larger than or equal to the width of the void in the first main surface and smaller than a thickness of the silicon carbide substrate when viewed in the direction parallel to the first main surface.

### TECHNICAL FIELD

The present disclosure relates to a silicon carbide substrate and a method of manufacturing a silicon carbide substrate. This application claims priority based on Japanese Patent Application No. 2021-178510 filed on Nov. 1, 2021, the entire contents of which are incorporated herein by reference.

### BACKGROUND ART

Japanese National Patent Publication No. 2010-514648 (PTL 1) describes a method of manufacturing a silicon carbide crystal that is completely free of micropipe defects.

### CITATION LIST

### Patent Literature

PTL 1: Japanese National Patent Publication No. 2010-514648

### SUMMARY OF INVENTION

A silicon carbide substrate according to the present disclosure includes a first main surface and a second main surface opposite to the first main surface. A void is present in the silicon carbide substrate. An area density of the void in the first main surface is 0.7/cm² or less. A width of the void is 10 μm to 80 μm when viewed in a direction perpendicular to the first main surface. In a cross section perpendicular to the first main surface, the width of the void decreases from the first main surface toward the second main surface when viewed in a direction parallel to the first main surface. A depth of the void is larger than or equal to the width of the void in the first main surface and smaller than a thickness of the silicon carbide substrate when viewed in the direction parallel to the first main surface. The first main surface is a silicon plane or a plane inclined in an off-direction relative to the silicon plane.

A method of manufacturing a silicon carbide substrate according to the present disclosure includes the following steps. A silicon carbide source material and a seed substrate are prepared. A silicon carbide crystal is grown on the seed substrate by sublimating the silicon carbide source material. After the growing a silicon carbide crystal, the silicon carbide crystal is cooled. In the cooling the silicon carbide crystal, a rate of cooling the silicon carbide crystal in a temperature range where the silicon carbide crystal has a temperature of 1400° C. to 1600° C. is 23° C./min to 36° C./min.

### BRIEF DESCRIPTION OF DRAWINGS

FIG. 1 is a schematic plan view showing the configuration of a silicon carbide substrate according to the present embodiment.

FIG. 2 is a schematic cross-sectional view taken along line II-II in FIG. 1.

FIG. 3 is an enlarged plan view of a region III in FIG. 1.

FIG. 4 is a schematic cross-sectional view taken along line IV-IV in FIG. 3.

FIG. 5 is an enlarged plan view of a region V in FIG. 1.

FIG. 6 is an enlarged plan view of a region VI in FIG. 1.

FIG. 7 is a schematic cross-sectional view taken along line VII-VII in FIG. 6.

FIG. 8 is a partial schematic cross-sectional view showing the configuration of a manufacturing apparatus for the silicon carbide crystal according to the present embodiment.

FIG. 9 is a flowchart schematically showing a method of manufacturing a silicon carbide substrate according to the present embodiment.

FIG. 10 is a schematic diagram showing the relationship between a temperature and a time.

FIG. 11 is a flowchart schematically showing a cooling step in the method of manufacturing a silicon carbide substrate according to the present embodiment.

FIG. 12 is a schematic cross-sectional view showing the configuration of the silicon carbide crystal after the cooling step.

FIG. 13 is an enlarged schematic view showing the configuration of a region XIII in FIG. 12.

FIG. 14 is a diagram showing the relationship between an area density of a void and a rate of cooling the silicon carbide crystal.

FIG. 15 is a diagram showing the relationship between a yield of a device and the area density of the void.

### DETAILED DESCRIPTION

### Problems to be Solved by Present Disclosure

An object of the present disclosure is to provide a silicon carbide substrate and a method of manufacturing a silicon carbide substrate in which the area density of a void can be reduced while the occurrence of a crack is suppressed.

### Advantageous Effects of Present Disclosure

According to the present disclosure, it is possible to provide a silicon carbide substrate and a method of manufacturing a silicon carbide substrate in which the area density of a void can be reduced while the occurrence of a crack is suppressed.

### Description of Embodiments of Present Disclosure

First, embodiments of the present disclosure will be listed and described.

(1) A silicon carbide substrate 100 according to the present disclosure includes a first main surface 1 and a second main surface 2 opposite to first main surface 1. A void 10 is present in silicon carbide substrate 100. An area density of void 10 in first main surface 1 is 0.7/cm² or less. A width of void 10 is 10 μm to 80 μm when viewed in a direction perpendicular to first main surface 1. The width of void 10 decreases from first main surface 1 toward second main surface 2 when viewed in a direction parallel to first main surface 1. In a cross section perpendicular to the first main surface 1, a depth of void 10 is larger than or equal to the width of void 10 in first main surface 1 and smaller than a thickness of silicon carbide substrate 100 when viewed in the direction parallel to first main surface 1. First main surface 1 is a silicon plane or a plane inclined in an off-direction relative to the silicon plane.

(2) In silicon carbide substrate 100 according to the above (1), the area density of void 10 in first main surface 1 may be 0.2/cm² or more.

(3) In silicon carbide substrate 100 according to the above (1) or (2), a micropipe defect 20 may be present in silicon carbide substrate 100. An area density of micropipe defect 20 in first main surface 1 may be 0.3/cm² or less.

(4) In silicon carbide substrate 100 according to any one of the above (1) to (3), a diameter of first main surface 1 may be 150 mm or more.

(5) In silicon carbide substrate 100 according to any one of the above (1) to (4), an off-angle of the plane inclined in the off-direction relative to the silicon plane may be 8° or less.

(6) A method of manufacturing silicon carbide substrate 100 according to the present disclosure includes the following steps. A silicon carbide source material 53 and a seed substrate 50 are prepared. A silicon carbide crystal 110 is grown on seed substrate 50 by sublimating silicon carbide source material 53. After the growing silicon carbide crystal 110, silicon carbide crystal 110 is cooled. In the cooling silicon carbide crystal 110, a rate of cooling silicon carbide crystal 110 in a temperature range where silicon carbide crystal 110 has a temperature of 1400° C. to 1600° C. is 23° C./min to 36° C./min.

(7) In the method of manufacturing silicon carbide substrate 100 according to the above (6), in the growing silicon carbide crystal 110 on seed substrate 50 by sublimating silicon carbide source material 53, silicon carbide crystal 110 may have a temperature of 2100° C. to 2300° C.

(8) In the method of manufacturing silicon carbide substrate 100 according to the above (6) or (7), in the cooling silicon carbide crystal 110, a rate of cooling silicon carbide crystal 110 in a temperature range where silicon carbide crystal 110 has a temperature of 1000° C. or more and less than 1400° C. may be less than 23° C./min.

### Details of Embodiments of Present Disclosure

The details of the embodiment of the present disclosure will now be described with reference to the drawings. In the drawings below, the same or corresponding elements are denoted by the same reference numerals, and the same description thereof will not be repeated. Regarding crystallographic denotation herein, an individual orientation, a group orientation, an individual plane, and a group plane are shown in [ ], < >, ( ), and { }, respectively. Furthermore, a crystallographically negative index is normally expressed by a number with a bar “-” thereabove, however, a negative sign herein precedes a number.

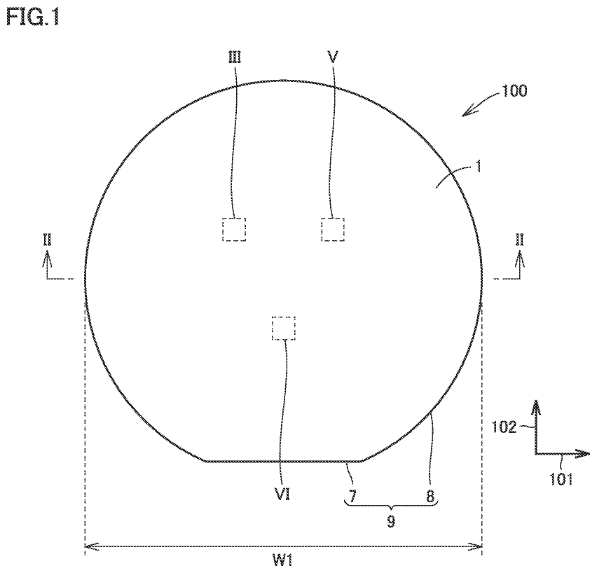

First, the configuration of silicon carbide substrate 100 according to the present embodiment will be described. FIG. 1 is a schematic plan view showing the configuration of silicon carbide substrate 100 according to the present embodiment.

As shown in FIG. 1, silicon carbide substrate 100 according to the present embodiment has a first main surface 1 and an outer peripheral side surface 9. First main surface 1 extends along each of a first direction 101 and a second direction 102. First direction 101 is not particularly limited, and is, for example, a <11-20> direction. Second direction 102 is not particularly limited, and is, for example, a <1-100> direction. The off-direction is, for example, first direction 101. Silicon carbide substrate 100 is made of, for example, hexagonal silicon carbide. The polytype of hexagonal silicon carbide is, for example, 4H. Silicon carbide substrate 100 contains, for example, an n-type impurity such as nitrogen.

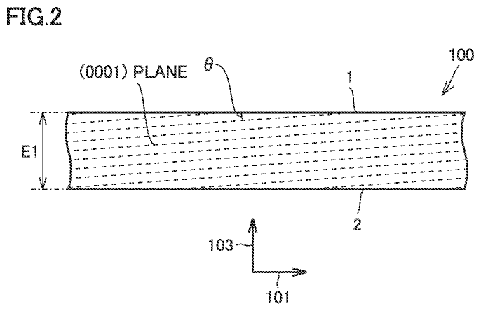

First main surface 1 is a silicon plane or a plane inclined in an off-direction relative to the silicon plane. In other words, first main surface 1 is a (0001) plane or a plane inclined in the off-direction relative to the (0001) plane. Similarly, a second main surface 2 (refer to FIG. 2) is a carbon plane or a plane inclined in the off-direction relative to the carbon plane. In other words, second main surface 2 is a (000-1) plane or a plane inclined in the off-direction relative to the (000-1) plane.

As shown in FIG. 1, outer peripheral side surface 9 includes an orientation flat portion 7 and an arc-shaped portion 8. Arc-shaped portion 8 is contiguous to orientation flat portion 7. As shown in FIG. 1, when viewed in a direction perpendicular to first main surface 1, orientation flat portion 7 extends along first direction 101.

A diameter W1 of first main surface 1 is, for example, 150 mm. Diameter W1 may be 150 mm or more, or may be 200 mm or more. Diameter W1 is not particularly limited, and may be, for example, 300 mm or less. When viewed in the direction perpendicular to first main surface 1, diameter W1 is the longest linear distance between two different points on outer peripheral side surface 9.

FIG. 2 is a schematic cross-sectional view taken along line II-II in FIG. 1. The cross section shown in FIG. 2 is perpendicular to first main surface 1 and parallel to first direction 101. As shown in FIG. 2, silicon carbide substrate 100 according to the present embodiment includes second main surface 2. Second main surface 2 is located opposite to first main surface 1. A thickness E1 of silicon carbide substrate 100 is, for example, 300 μm to 700 μm. A third direction 103 is a direction perpendicular to each of first direction 101 and second direction 102. A thickness direction of silicon carbide substrate 100 is the same as third direction 103.

When first main surface 1 is inclined in the off-direction relative to the silicon plane, an off-angle θ of the plane inclined in the off-direction relative to the silicon plane may be 8° or less. Off-angle θ is not particularly limited, and may be, for example, 6° or less, or may be 4° or less. Off-angle θ is not particularly limited, and may be, for example, 1° or more, or may be 2° or more. The off-direction of the plane inclined in the off-direction relative to the silicon plane is not particularly limited, and is, for example, the <11-20> direction.

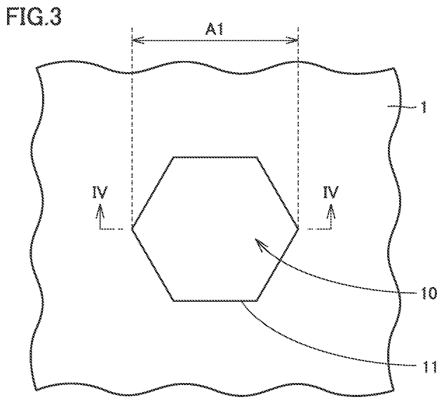

FIG. 3 is an enlarged plan view of a region III of FIG. 1. In silicon carbide substrate 100 according to the present embodiment, at least one void 10 is present. As shown in FIG. 3, when viewed in the direction perpendicular to first main surface 1, the shape of an opening 11 of void 10 is not particularly limited, and is, for example, a hexagon. Opening 11 of void 10 may have a shape other than a hexagon. Void 10 is not accompanied by a threading screw dislocation. From another viewpoint, void 10 is not contiguous to the threading screw dislocation.

When viewed in the direction perpendicular to first main surface 1, the width of void 10 (a first width A1) is 10 μm to 80 μm. The width of void 10 is the maximum value of the width between any two points at opening 11 of void 10. The width of void 10 may be, for example, a width along the off-direction. The value of first width A1 is not particularly limited, and may be, for example, 20 μm or more, or may be 30 μm or more. The value of first width A1 is not particularly limited, and may be, for example, 70 m or less, or may be 60 μm or less.

According to silicon carbide substrate 100 of the present embodiment, an area density of void 10 in first main surface 1 is 0.7/cm² or less. The area density of void 10 is not particularly limited, and may be, for example, 0.6/cm² or less, or 0.5/cm² or less. The area density of void 10 is, for example, 0.2/cm² or more. The area density of void 10 is not particularly limited, and may be, for example, 0.25/cm² or more, or 0.3/cm² or more.

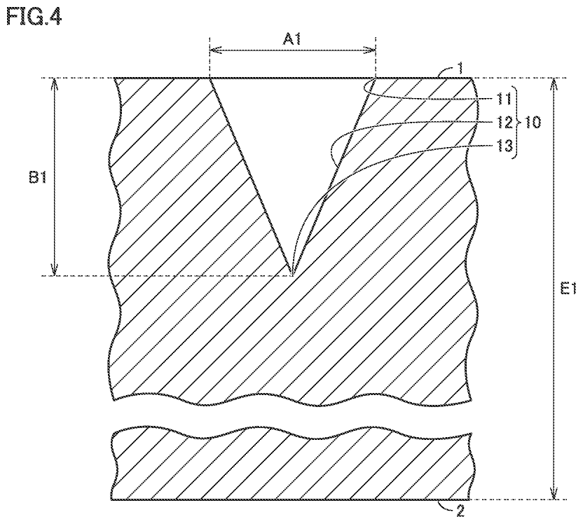

FIG. 4 is a schematic cross-sectional view taken along line IV-IV in FIG. 3. The cross section shown in FIG. 4 is perpendicular to first main surface 1 and parallel to first direction 101. As shown in FIG. 4, the width of void 10 (first width A1) decreases from first main surface 1 toward second main surface 2 when viewed in a direction parallel to first main surface 1. Void 10 is provided with opening 11, a first side surface portion 12, and a bottom portion 13. Opening 11 is located at first main surface 1. Bottom portion 13 is located between first main surface 1 and second main surface 2. First side surface portion 12 is located between opening 11 and bottom portion 13. When viewed in the direction parallel to first main surface 1, first side surface portion 12 may be linear.

As shown in FIG. 4, the shape of void 10 is, for example, a triangle when viewed in the direction parallel to first main surface 1. The base of the triangle is located at opening 11. The vertex of the triangle corresponds to bottom portion 13 of void 10. A direction perpendicular to the base of the triangle is the thickness direction of silicon carbide substrate 100. The triangle is, for example, an isosceles triangle. The width of opening 11 corresponds to first width A1. First side surface portion 12 is inclined relative to third direction 103 (refer to FIG. 2). In three dimensions, void 10 may be hexagonal pyramidal.

As shown in FIG. 4, the depth of void 10 (a first depth B1) is equal to or greater than the width of void 10 (first width A1) in first main surface 1 when viewed in the direction parallel to first main surface 1. In other words, first depth B1 may be equal to first width A1 or may be larger than first width A1. The depth of void 10 is not particularly limited, and may be, for example, three times or less as large as the width of void 10, or may be two times or less as large as the width of void 10.

The depth of void 10 is less than the thickness of silicon carbide substrate 100. In other words, void 10 does not penetrate silicon carbide substrate 100. Void 10 is exposed only at first main surface 1, and is not exposed at second main surface 2. In another embodiment, void 10 may be exposed only at second main surface 2 and may not be exposed at first main surface 1. In this case, opening 11 of void 10 is located at second main surface 2.

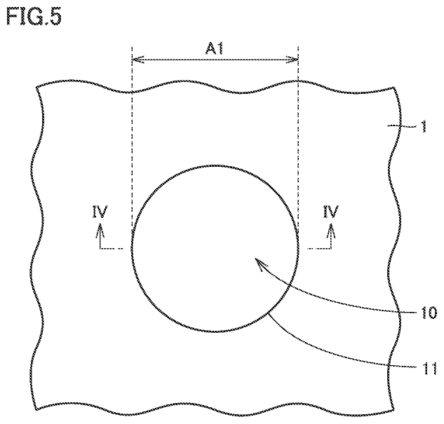

FIG. 5 is an enlarged plan view of a region V in FIG. 1. As shown in FIG. 3, the shape of opening 11 of void 10 may be, for example, a circle when viewed in the direction perpendicular to first main surface 1. In three dimensions, void 10 may be conical. The cross-sectional shape of void 10 shown in FIG. 5 is the same as the shape shown in FIG. 4. The shape of opening 11 of void 10 is not particularly limited, and may be, for example, an ellipse or a polygon other than a hexagon.

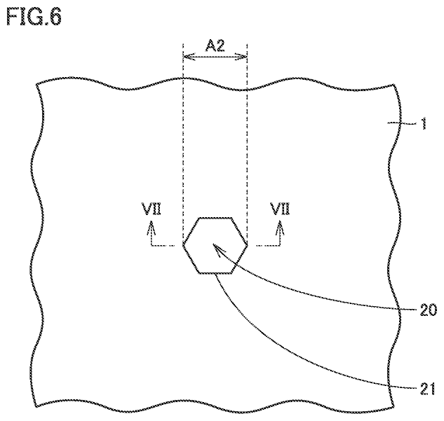

FIG. 6 is an enlarged plan view of a region VI in FIG. 1. In silicon carbide substrate 100 according to the present embodiment, at least one micropipe defect 20 may be present. As shown in FIG. 6, the shape of micropipe defect 20 is, for example, a hexagon when viewed in the direction perpendicular to first main surface 1. Micropipe defect 20 is accompanied by a threading screw dislocation.

When viewed in the direction perpendicular to first main surface 1, the width of micropipe defect 20 (a second width A2) is, for example, from 1 μm to 8 μm. The width of micropipe defect 20 is the maximum value of the width between any two points at a first opening 21 of micropipe defect 20. The width of micropipe defect 20 may be, for example, a width along the off-direction. The width of void 10 (first width A1) may be five times or more as large as the width of micropipe defect 20 (second width A2), or may be ten times or more as large as second width A2.

According to silicon carbide substrate 100 of the present embodiment, an area density of micropipe defect 20 in first main surface 1 is, for example, 0.3/cm² or less. The area density of micropipe defect 20 is not particularly limited, and may be, for example, 0.25/cm² or less, or may be, for example, 0.2/cm² or less. The area density of micropipe defect 20 is not particularly limited, and may be, for example, 0.01/cm² or more, or may be, for example, 0.05/cm² or more.

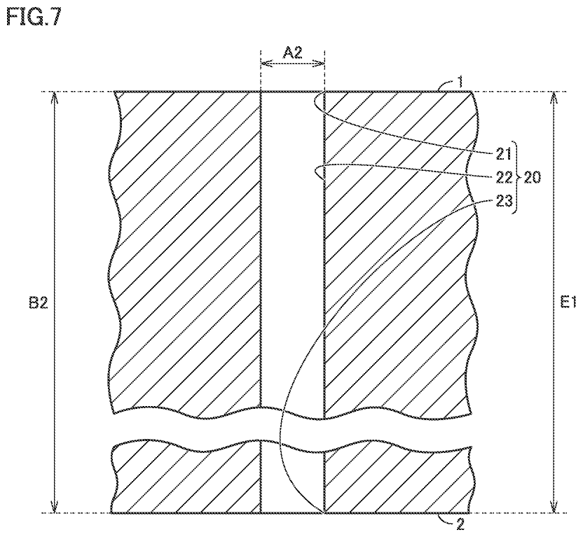

FIG. 7 is a schematic cross-sectional view taken along line VII-VII in FIG. 6. The cross section shown in FIG. 7 is perpendicular to first main surface 1 and parallel to first direction 101. As shown in FIG. 7, micropipe defect 20 penetrates silicon carbide substrate 100. Micropipe defect 20 is opened at each of first main surface 1 and second main surface 2.

Micropipe defect 20 is provided with first opening 21, a second side surface portion 22, and a second opening 23. First opening 21 is located at first main surface 1. Second opening 23 is located at second main surface 2. Second side surface portion 22 is located between first opening 21 and second opening 23. When viewed in the direction parallel to first main surface 1, second side surface portion 22 extends in a direction substantially perpendicular to first main surface 1.

As shown in FIG. 7, a length of micropipe defect 20 (a second length B2) in the direction perpendicular to first main surface 1 is substantially equal to thickness E1 of silicon carbide substrate 100. Second length B2 is larger than second width A2. Second length B2 may be 25 times or more as large as second width A2, or may be 50 times or more as large as second width A2.

Next, the configuration of a manufacturing apparatus for the silicon carbide crystal according to the present embodiment will be described.

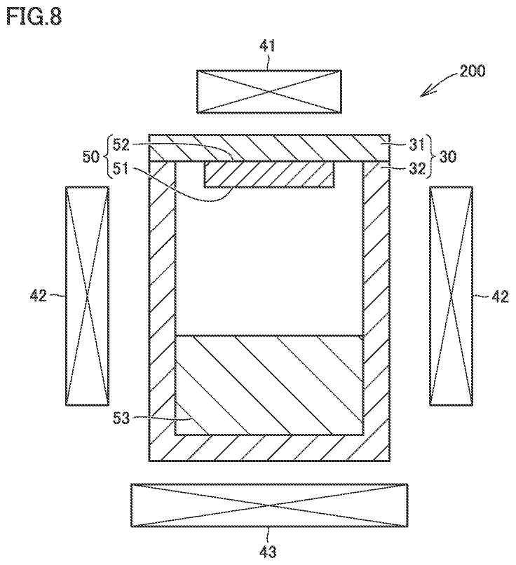

FIG. 8 is a partial schematic cross-sectional view showing the configuration of the manufacturing apparatus for the silicon carbide crystal according to the present embodiment. As shown in FIG. 8, a manufacturing apparatus 200 for the silicon carbide crystal mainly includes a crucible 30, a first resistive heater 41, a second resistive heater 42, and a third resistive heater 43. Crucible 30 has a source material container portion 32 and a lid portion 31. Lid portion 31 is disposed on the top of source material container portion 32.

First resistive heater 41 is disposed above lid portion 31. Second resistive heater 42 is disposed so as to surround the outer periphery of source material container portion 32. Third resistive heater 43 is disposed below the bottom surface of source material container portion 32. Crucible 30 is heated by applying electric power to first resistive heater 41, second resistive heater 42, and third resistive heater 43.

Next, a method of manufacturing silicon carbide substrate 100 according to the present embodiment will be described.

As shown in FIG. 8, a silicon carbide source material 53 is disposed in source material container portion 32. Silicon carbide source material 53 is, for example, a polycrystalline silicon carbide powder. A seed substrate 50 is fixed to lid portion 31 by using, for example, an adhesive (not shown). Seed substrate 50 has a growth surface 51 and an attachment surface 52. Attachment surface 52 is opposite to growth surface 51. Growth surface 51 faces silicon carbide source material 53. Attachment surface 52 faces lid portion 31. Growth surface 51 of seed substrate 50 is disposed to face the surface of silicon carbide source material 53.

Seed substrate 50 is, for example, a hexagonal silicon carbide substrate whose polytype is 4H. A diameter of growth surface 51 is, for example, 150 mm. The diameter of growth surface 51 may be 150 mm or more. Growth surface 51 is, for example, a {0001} plane or a plane inclined by an off-angle of approximately 8° or less relative to the {0001} plane. As described above, seed substrate 50 and silicon carbide source material 53 are prepared.

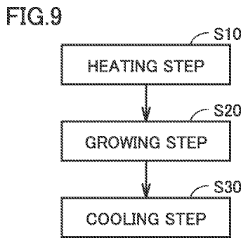

FIG. 9 is a flowchart schematically showing a method of manufacturing silicon carbide substrate 100 according to the present embodiment. As shown in FIG. 9, the method of manufacturing silicon carbide substrate 100 according to the present embodiment mainly includes a heating step (S10), a growing step (S20), and a cooling step (S30).

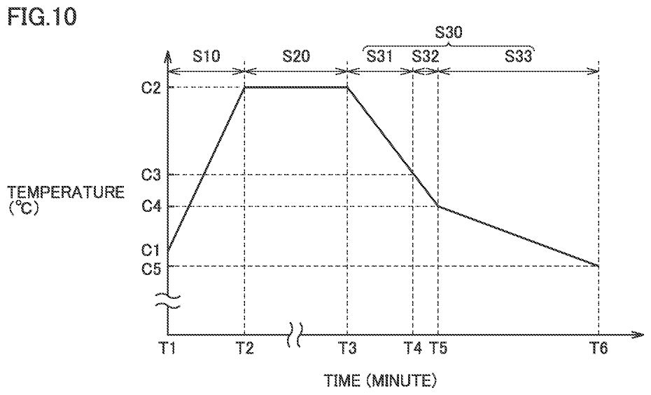

FIG. 10 is a schematic view showing the relationship between a temperature and a time. In FIG. 10, a vertical axis represents the temperature and a horizontal axis represents the time. As shown in FIG. 10, in the heating step (S10), the temperature of growth surface 51 of seed substrate 50 is raised from a first temperature C1 to a second temperature C2 in crucible 30 from a first time point T1 to a second time point T2. First temperature C1 is, for example, 1100° C. Second temperature C2 is, for example, 2200° C. In the heating step (S10), while the temperatures of seed substrate 50 and silicon carbide source material 53 disposed in crucible 30 are raised, the pressure of an ambient gas in crucible 30 is maintained at, for example, about 80 kPa. The ambient gas includes, for example, an inert gas such as an argon gas, a helium gas, or a nitrogen gas.

Next, a growing step (S20) is performed. With the temperature of growth surface 51 of seed substrate 50 being lower than the temperature of silicon carbide source material 53, the pressure in crucible 30 is reduced. The pressure of the ambient gas in crucible 30 is reduced to, for example, 1.0 kPa. As a result, silicon carbide source material 53 starts to sublimate, and the sublimated silicon carbide gas is recrystallized on growth surface 51 of seed substrate 50. A silicon carbide crystal 110 begins to grow as a single crystal on growth surface 51 of seed substrate 50. During the growth of silicon carbide crystal 110, the pressure in crucible 30 is maintained at, for example, about 0.1 kPa to 3 kPa.

Specifically, silicon carbide crystal 110 continues to grow on growth surface 51 of seed substrate 50 from second time point T2 to a third time point T3. From second time point T2 to third time point T3, the temperature of silicon carbide crystal 110 is maintained substantially at second temperature C2. The temperature of silicon carbide crystal 110 is defined as the temperature of a portion of silicon carbide crystal 110 in contact with growth surface 51 of seed substrate 50. As described above, silicon carbide crystal 110 is grown on seed substrate 50 by sublimating silicon carbide source material 53. In the growing step (S20), the temperature of silicon carbide crystal 110 is, for example, from 2100° C. to 2300° C. The temperature of silicon carbide crystal 110 is not particularly limited, and may be, for example, 2125° C. or higher, or 2150° C. or higher. The temperature of silicon carbide crystal 110 is not particularly limited, and may be, for example, 2250° C. or lower, or 2275° C. or lower.

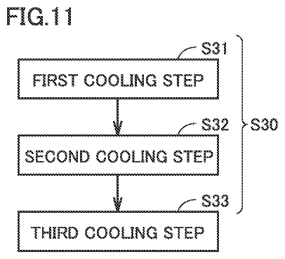

Next, the cooling step (S30) is performed. After silicon carbide crystal 110 is grown on seed substrate 50, silicon carbide crystal 110 is cooled. FIG. 11 is a flowchart schematically showing the cooling step in the method of manufacturing silicon carbide substrate 100 according to the present embodiment. As shown in FIG. 11, the cooling step (S30) mainly includes a first cooling step (S31), a second cooling step (S32), and a third cooling step (S33).

First, a first cooling step (S31) is performed. As shown in FIG. 10, in the first cooling step (S31), silicon carbide crystal 110 is cooled from second temperature C2 to a third temperature C3 from third time point T3 to a fourth time point T4. Third temperature C3 is, for example, 1600° C.

Next, a second cooling step (S32) is performed. As shown in FIG. 10, in the second cooling step (S32), silicon carbide crystal 110 is cooled from third temperature C3 to a fourth temperature C4 from fourth time point T4 to a fifth time point T5. Fourth temperature C4 is, for example, 1400° C.

A rate of cooling silicon carbide crystal 110 in a temperature range where the silicon carbide crystal 110 has a temperature of 1400° C. to 1600° C. is 23° C./min to 36° C./min. In other words, the rate of cooling silicon carbide crystal 110 in the second cooling step (S32) is 23° C./min to 36° C./min. The rate of cooling silicon carbide crystal 110 in the second cooling step (S32) is defined as a value obtained by dividing a temperature obtained by subtracting fourth temperature C4 from third temperature C3 by a time from fourth time point T4 to fifth time point T5.

The rate of cooling silicon carbide crystal 110 in the second cooling step (S32) is not particularly limited, and may be, for example, 25° C./min or more, or 27° C./min or more. The rate of cooling silicon carbide crystal 110 in the second cooling step (S32) is not particularly limited, and may be, for example, 34° C./min or less, or 32° C./min or less.

Next, a third cooling step (S33) is performed. As shown in FIG. 10, in the third cooling step (S33), silicon carbide crystal 110 is cooled from fourth temperature C4 to a fifth temperature C5 from fifth time point T5 to a sixth time point T6. Fifth temperature C5 is, for example, 1000° C.

The rate of cooling silicon carbide crystal 110 in a temperature range where the temperature of silicon carbide crystal 110 is 1000° C. or more and less than 1400° C. may be less than 23° C./min. In other words, the rate of cooling silicon carbide crystal 110 in the third cooling step (S33) is less than 23° C./min. The rate of cooling silicon carbide crystal 110 in the third cooling step (S33) is a value obtained by dividing a temperature obtained by subtracting fifth temperature C5 from fourth temperature C4 by a time from fifth time point T5 to sixth time point T6.

The rate of cooling silicon carbide crystal 110 in the third cooling step (S33) is not particularly limited, and may be, for example, 1° C./min or more, or 5° C./min or more. The rate of cooling silicon carbide crystal 110 in the third cooling step (S33) is not particularly limited, and may be, for example, 20° C./min or less, 15° C./min or less, or 10° C./min or less.

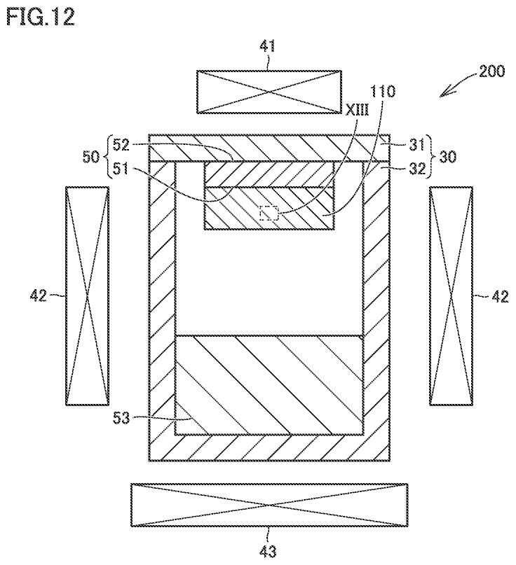

FIG. 12 is a schematic cross-sectional view showing the configuration of silicon carbide crystal 110 after the cooling step. As shown in FIG. 12, silicon carbide crystal 110 is formed under seed substrate 50. A direction from seed substrate 50 toward silicon carbide source material 53 is a growth direction of silicon carbide crystal 110.

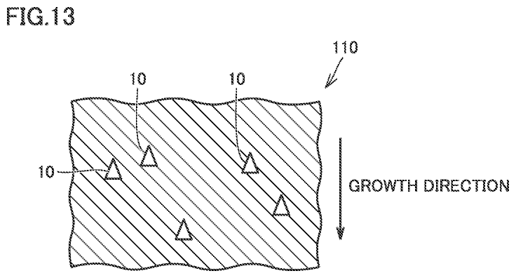

FIG. 13 is an enlarged schematic view showing the configuration of a region XIII in FIG. 12. As shown in FIG. 13, void 10 is formed inside silicon carbide crystal 110. In a cross section parallel to the growth direction of silicon carbide crystal 110, void 10 has, for example, a triangular shape. The width of void 10 in a direction perpendicular to the growth direction of silicon carbide crystal 110 increases toward the growth direction of silicon carbide crystal 110. From another viewpoint, the width of void 10 in the direction perpendicular to the growth direction of silicon carbide crystal 110 increases from seed substrate 50 toward silicon carbide source material 53.

Next, silicon carbide crystal 110 is sliced. Specifically, silicon carbide crystal 110 is sliced along a plane perpendicular to the central axis of silicon carbide crystal 110 using a saw wire, for example. As a result, a plurality of silicon carbide substrates 100 is obtained (refer to FIG. 1).

Next, functions and effects of silicon carbide substrate 100 and the method of manufacturing silicon carbide substrate 100 according to the present embodiment will be described.

In order to calculate the area density of micropipe defect 20 in silicon carbide substrate 100, an etching method is generally used. Micropipe defect 20 is accompanied by a threading screw dislocation. Therefore, the vicinity of micropipe defect 20 is etched by chlorine or the like, and thus a pit having a specific shape is formed on the surface of silicon carbide substrate 100. The area density of micropipe defect 20 is calculated by calculating the number of pits per unit area.

In general, the higher the area density of micropipe defect 20 in silicon carbide substrate 100, the higher the defective ratio of the silicon carbide semiconductor device manufactured using silicon carbide substrate 100. However, even when the area density of micropipe defect 20 in silicon carbide substrate 100 is low (for example, 0.1/cm² or less), the defective ratio of silicon carbide semiconductor device may be high.

In order to investigate the cause of the above phenomenon in detail, the inventors observed the surface of silicon carbide substrate 100 with an optical microscope after polishing silicon carbide substrate 100. As a result, the inventors found that a new defect (referred to as void 10) different from micropipe defect 20 was present in silicon carbide substrate 100. Further investigation revealed that the width of void 10 decreased from the front surface (first main surface 1) of silicon carbide substrate 100 toward the back surface (second main surface 2). The depth of void 10 was equal to or greater than the width of void 10 at the surface (first main surface 1) and less than the thickness of silicon carbide substrate 100. Furthermore, void 10 was not accompanied by a threading screw dislocation. Therefore, it is considered that void 10 was undetectable by the etching method because void 10 was not enlarged by etching with chlorine or the like.

The inventors investigated in detail the relationship between the position of micropipe defect 20 in the surface of silicon carbide substrate 100, the position of void 10 in the surface, and the position (address) of the silicon carbide semiconductor device manufactured using silicon carbide substrate 100, and confirmed that the address of a defective silicon carbide semiconductor device coincided with the position in silicon carbide substrate 100 where micropipe defect 20 or void 10 was present. That is, it was found that void 10 newly discovered by the inventors was one of the causes that give rise to a defective silicon carbide semiconductor device.

The inventors conducted intensive studies on the cause of the generation of void 10, and as a result, obtained the following findings and found a method of manufacturing silicon carbide substrate 100 according to the present embodiment. Specifically, it was found that there was a strong correlation between the cooling rate in the step of cooling silicon carbide crystal 110 and the generation rate of void 10. It was considered that, in the step of cooling silicon carbide crystal 110, vacancies present in silicon carbide crystal 110 were supersaturated and precipitated as crystal defects, and thus voids 10 was generated in silicon carbide crystal 110.

The inventors have conceived that the rate of cooling silicon carbide crystal 110 is increased to suppress the vacancies from being supersaturated, thereby suppressing the generation of voids 10. On the other hand, it was found that when the rate of cooling silicon carbide crystal 110 was too high, stress relaxation in silicon carbide crystal 110 was insufficient, resulting in the occurrence of a crack in silicon carbide crystal 110.

In the method of manufacturing silicon carbide substrate 100 according to the present embodiment, in the step of cooling silicon carbide crystal 110, the rate of cooling silicon carbide crystal 110 in a temperature range where silicon carbide crystal 110 has a temperature of 1400° C. to 1600° C. is 23° C./min to 36° C./min. This makes it possible to reduce the area density of void 10 while suppressing the occurrence of a crack.

In the method of manufacturing silicon carbide substrate 100 according to the present embodiment, in the step of growing silicon carbide crystal 110 on seed substrate 50 by sublimating silicon carbide source material 53, seed substrate 50 may have a temperature of 2100° C. to 2300° C. The concentration of the vacancies formed in silicon carbide crystal 110 increases as the temperature increases. It is considered that the area density of void 10 generated due to the vacancies increases when the concentration of the vacancies is high. Therefore, by setting the temperature of seed substrate 50 to 2300° C. or lower, it is possible to suppress an increase in the area density of void 10 generated in silicon carbide crystal 110 formed on seed substrate 50. Further, by setting the temperature of seed substrate 50 to 2100° C. or higher, it is possible to suppress the deterioration in the quality of silicon carbide crystal 110 grown on seed substrate 50.

In the method of manufacturing silicon carbide substrate 100 according to the present embodiment, in the step of cooling silicon carbide crystal 110, the rate of cooling silicon carbide crystal 110 in a temperature range where silicon carbide crystal 110 has a temperature of 1000° C. to 1400° C. may be less than 23° C./min. This can further suppress the occurrence of a crack.

Furthermore, according to silicon carbide substrate 100 of the present embodiment, the area density of void 10 is 0.7/cm² or less. This can improve the yield of a silicon carbide semiconductor device manufactured using silicon carbide substrate 100 according to the present embodiment.

### Example 1

### (Sample Preparation)

In Example 1, silicon carbide crystal 110 was manufactured under a condition of a growth temperature (second temperature C2) of 2150° C. for a group (first group) and under a condition of a growth temperature (second temperature C2) of 2300° C. for another group (second group) in the growing step (S20). Silicon carbide crystals 110 in each group were manufactured using the temperature profile shown in FIG. 10. First temperature C1 was set to 1100° C. Third temperature C3 was set to 1600° C. Fourth temperature C4 was set to 1400° C. Fifth temperature C5 was set to 1000° C.

In the first group, the cooling rate in the second cooling step (S32) was changed in a range of 2° C./min to 33° C./min. In the second group, the cooling rate in the second cooling step (S32) was changed in a range of 3° C./min to 48° C./min. After silicon carbide crystals 110 were manufactured, silicon carbide crystals 110 were sliced using a saw wire to cut a plurality of silicon carbide substrates 100. Mechanical polishing was performed on each of first main surfaces 1 and second main surfaces 2 of silicon carbide substrates 100.

### (Measurement Method)

In each of the first group and the second group, silicon carbide substrates 100 were obtained from silicon carbide crystals 110 cooled at different cooling rates. The area density of void 10 was measured for all silicon carbide substrates 100. Specifically, the number of voids 10 was measured in first main surface 1 of each of silicon carbide substrates 100. Void 10 was identified by using an optical microscope. A bottomed hole having a width of 10 μm to 80 μm when viewed in a direction perpendicular to first main surface 1 and having the width that decreases from first main surface 1 toward second main surface 2 was identified as void 10. The value obtained by dividing the number of voids 10 in first main surface 1 by the area of first main surface 1 was defined as the area density of void 10.

### (Measurement Results)

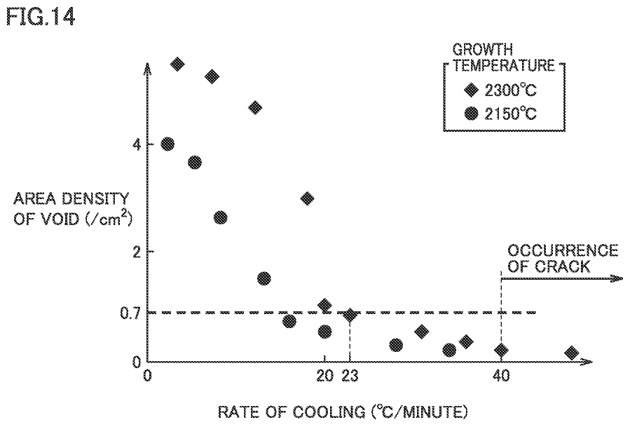

FIG. 14 is a diagram showing the relationship between the area density of void 10 and the rate of cooling silicon carbide crystal 110. As shown in FIG. 14, when silicon carbide substrates 100 manufactured at the same cooling rate were compared, it was confirmed that the area densities of void 10 in silicon carbide substrates 100 manufactured at the low growth temperature (2150° C.) were lower than the area densities of void 10 in silicon carbide substrates 100 manufactured at the high growth temperature (2300° C.).

When silicon carbide substrates 100 manufactured at the same growth temperature were compared, it was confirmed that the area densities of void 10 in silicon carbide substrates 100 manufactured at a high cooling rate were lower than the area densities of void 10 in silicon carbide substrates 100 manufactured at a low cooling rate. From the above results, it was confirmed that the area density of void 10 was able to be reduced by increasing the cooling rate in the second cooling step. Specifically, when the growth temperature was 2300° C., the area density of void 10 in silicon carbide substrate 100 was able to be 0.7/cm² or less by setting the cooling rate in the second cooling step to 23° C./min or more.

On the other hand, in silicon carbide crystals 110 manufactured at a cooling rate of 40° C./min or more in the second cooling step, the occurrence of a crack was confirmed. The crack is an elongated fracture having a length of 100 μm or more. From the above results, it was confirmed that by setting the cooling rate in the second cooling step to 23° C./min or more and less than 40° C./min, silicon carbide substrate 100 in which occurrence of a crack was suppressed and the area density of voids 10 was reduced was obtained.

### Example 2

### (Sample Preparation)

In Example 2, silicon carbide substrates 100 were divided into a group (third group) in which micropipe defect 20 had an area density of 0/cm², a group (fourth group) in which micropipe defect 20 had an area density of 0.3/cm², and a group (fifth group) in which micropipe defect 20 had an area density of 0.8/cm², and the relationship between the yield of a device and the area density of void 10 was investigated.

In silicon carbide substrates 100 of the third group, the area densities of void 10 were changed in a range of 0.2/cm² to 2.0/cm². In silicon carbide substrates 100 of the fourth group, the area densities of void 10 were changed in a range of 0.3/cm² to 1.8/cm². In silicon carbide substrates 100 of the fifth group, the area densities of void 10 were changed between 0.2/cm² to 1.6/cm².

### (Measurement Method)

Silicon carbide epitaxial layers were formed on silicon carbide substrates 100 in each group, and devices were manufactured. The devices were metal oxide semiconductor field effect transistors (MOSFET). For silicon carbide substrates 100 of each group, the yield of the device whose reverse voltage characteristics satisfy a required specification was calculated.

### (Measurement Results)

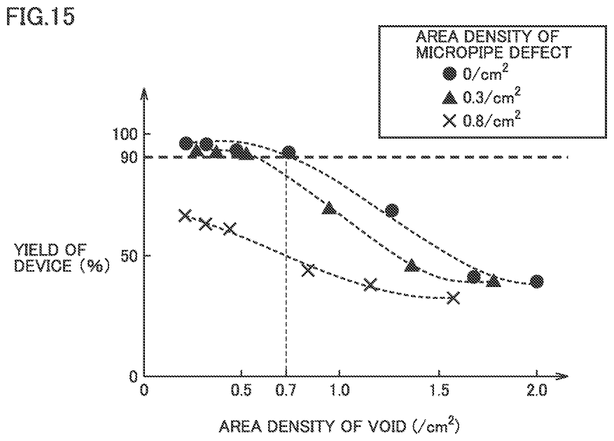

FIG. 15 is a diagram showing the relationship between the yield of the device and the area density of void 10. As shown in FIG. 15, when silicon carbide substrates 100 having the same area density of micropipe defect 20 were compared, it was confirmed that the yield of the device manufactured using silicon carbide substrates 100 having a low area density of void 10 was higher than the yield of the device manufactured using silicon carbide substrates 100 having a high area density of void 10.

When silicon carbide substrates 100 having the same area density of voids 10 were compared, it was confirmed that the yield of the device manufactured using silicon carbide substrates 100 having a low area density of micropipe defect 20 was higher than the yield of the device manufactured using silicon carbide substrates 100 having a high area density of micropipe defect 20. It was confirmed that, in order to achieve a device yield of 90% or more, it was desirable to set the area density of micropipe defect 20 to 0.3/cm² or less and the area density of void 10 to 0.7/cm² or less.

It should be understood that the embodiments and examples disclosed herein are illustrative and non-restrictive in every respect. The scope of the present invention is defined by the terms of the claims rather than the above description, and is intended to include any modifications within the scope and meaning equivalent to the terms of the claims.

### REFERENCE SIGNS LIST

1 first main surface; 2 second main surface; 7 orientation flat portion; 8 arc-shaped portion; 9 outer peripheral side surface; 10 void; 11 opening; 12 first side surface portion; 13 bottom portion; 20 micropipe defect; 21 first opening; 22 second side surface portion; 23 second opening; 30 crucible; 31 lid portion; 32 source material container portion; 41 first resistive heater; 42 second resistive heater; 43 third resistive heater; 50 seed substrate; 51 growth surface; 52 attachment surface; 53 silicon carbide source material; 100 silicon carbide substrate; 101 first direction; 102 second direction; 103 third direction; 110 silicon carbide crystal; 200 manufacturing apparatus; A1 first width; A2 second width; B1 first depth; B2 second length; C1 first temperature; C2 second temperature; C3 third temperature; C4 fourth temperature; C5 fifth temperature; E1 thickness; T1 first time point; T2 second time point; T3 third time point; T4 fourth time point; T5 fifth time point; T6 sixth time point; W1 diameter; θ off-angle.

1. A silicon carbide substrate comprising:
a first main surface; and
a second main surface opposite to the first main surface,
wherein a void is present in the silicon carbide substrate,
an area density of the void in the first main surface is 0.7/cm² or less,
a width of the void is 10 μm to 80 μm when viewed in a direction perpendicular to the first main surface,
in a cross section perpendicular to the first main surface, the width of the void decreases from the first main surface toward the second main surface when viewed in a direction parallel to the first main surface,
a depth of the void is larger than or equal to the width of the void in the first main surface and smaller than a thickness of the silicon carbide substrate when viewed in the direction parallel to the first main surface, and
the first main surface is a silicon plane or a plane inclined in an off-direction relative to the silicon plane.

2. The silicon carbide substrate according to claim 1, wherein the area density of the void in the first main surface is 0.2/cm² or more.

3. The silicon carbide substrate according to claim 1, wherein a micropipe defect is present in the silicon carbide substrate, and
an area density of the micropipe defect in the first main surface is 0.3/cm² or less.

4. The silicon carbide substrate according to claim 1, wherein a diameter of the first main surface is 150 mm or more.

5. The silicon carbide substrate according to claim 1, wherein an off-angle of the plane inclined in the off-direction is 8° or less.

6. A method of manufacturing a silicon carbide substrate, the method comprising:
preparing a silicon carbide source material and a seed substrate;
growing a silicon carbide crystal on the seed substrate by sublimating the silicon carbide source material; and
after the growing a silicon carbide crystal, cooling the silicon carbide crystal,
wherein in the cooling the silicon carbide crystal, a rate of cooling the silicon carbide crystal in a temperature range where the silicon carbide crystal has a temperature of 1400° C. to 1600° C. is 23° C./min to 36° C./min.

7. The method of manufacturing a silicon carbide substrate according to claim 6, wherein in the growing a silicon carbide crystal on the seed substrate by sublimating the silicon carbide source material, the silicon carbide crystal has a temperature of 2100° C. to 2300° C.

8. The method of manufacturing a silicon carbide substrate according to claim 6, wherein in the cooling the silicon carbide crystal, a rate of cooling the silicon carbide crystal in a temperature range where the silicon carbide crystal has a temperature of 1000° C. or more and less than 1400° C. is less than 23° C./min.
